(19) United States
(12) Patent Application Publication
(10) Pub. No.: US 2007/0023841 A1
(43) Pub. Date: Feb. 1, 2007

(54) Transistor and method for forming the same

(75) Inventor: Dae Kyeun Kim, Yongin-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/493,298

(22) Filed: Jul. 25, 2006

(30) Foreign Application Priority Data
Jul. 26, 2005 (KR) 10-2005-0067896

(51) Int. Cl. H01L 29/94

(52) U.S. Cl. 257/368

(57) ABSTRACT

Disclosed are a transistor and a method for forming the same. The present transistor comprises: a groove formed in a semiconductor substrate; a couple of first sidewall spacers formed in inner sidewalls of the groove, protruding over the substrate; a gate electrode formed between the first sidewall spacers; a gate insulating layer interposed between the gate electrode and the substrate; and source and drain regions formed in the substrate beside the groove.

This application claims the benefit of Korean Application No. 10-2005-0067896, filed on Jul. 26, 2005, which is incorporated by reference herein in its entirety.

### BACKGROUND OF THE INVENTION

1. Field of the Invention

The present invention relates to a semiconductor device and a fabrication method thereof. More specifically, the present invention relates to a transistor, as a semiconductor device or a component thereof (e.g., a chip or monolithic integrated circuit), in which a GIDL (Gate Induced Drain Leakage) phenomenon can be reduced or prevented, and a method forming the same.

2. Description of the Related Art

In general, a semiconductor device is fabricated with a plurality of passive and active circuit elements functioning as logic circuits, data storage circuits, and the like. A transistor has been used as one of representative active circuit elements for various functions such as switching, distributing of voltage/current, reception and/or outputting of signals, and so on. Especially, a transistor generally exhibits its performance according to a given design rule. However, characteristics of the fabricated transistor often depart from the design rule, because processing variables and/or structural variations occur in fabrication thereof.

FIGS. 1 to 3 are cross-sectional views illustrating problems in a conventional method for forming a transistor.

Referring to FIG. 1, in the conventional fabrication method, a gate insulating layer 12 is formed on a semiconductor substrate 10, and then a conductive layer 14 for a gate electrode is formed on the gate insulating layer 12.

Referring to FIG. 2, the conductive layer 14 is patterned to form a gate electrode 14a. In this patterning process, the gate insulating layer 12 may remain or be patterned to form a gate insulating layer pattern 12a. In a typical manufacturing method of semiconductor devices, a fine pattern such as a gate electrode can be formed using an anisotropic plasma etching process. During the formation of the gate electrode 14a, sidewalls of the gate electrode 14a and the gate insulating layer 12 may be damaged by the plasma, thus resulting in defects therein. Especially, as shown in FIG. 2, the vicinities of the lower edge of the gate electrode 14a may be damaged by the plasma so that the gate insulating layer in such regions can deteriorate, resulting in a relatively high trap density and a transistor that may be vulnerable to charge leakage.

Referring to FIG. 3, source/drain regions 20a and 20d are formed under and adjacent to opposed sides of the gate electrode 14a. Here, the damaged gate insulating layer 12a in the vicinity of lower edges of the gate electrode 14a may act as trap-sites of hot carriers that generate in a channel near the drain region 20d, and also may offer current leakage routes that may cause operational failures of transistors. Conventionally, source/drain regions 20s and 20d comprise low concentration regions which are formed by implantation of impurities in the substrate 50 closely to both sides of the gate electrode 14a, and heavy concentration regions which are formed by implantation of impurities after forming sidewall spacers 18. In such double junction structures of source/drain regions, the transistor can be protected from a hot carrier injection and a short channel effect. However, a GIDL (Gate Induced Drain Leakage) phenomenon may occur in regions 22, indicated by circles in FIG. 3, where the source/drain diffusion regions 20s and 20d partially overlap with the gate electrode 14a, which may result in an operational failure of the transistor.

### SUMMARY OF THE INVENTION

It is, therefore, an object of the present invention to provide a transistor and a method for forming the same, wherein sidewalls of a gate electrode and a gate insulating layer are rarely damaged during an anisotropic etching process, and that can reduce or prevent a GIDL phenomenon.

To achieve the above object, an embodiment of a transistor according to the present invention, comprises: a trench or groove in a semiconductor substrate; first sidewall spacers formed in inner sidewalls of the trench or groove, extending over an uppermost surface of the substrate; a gate electrode between the first sidewall spacers; a gate insulating layer between the gate electrode and the substrate; and source and drain regions in the substrate beside the trench or groove.

Because of the first sidewall spacers at both sides of the gate electrode, the source and drain regions can be separated from each other by a lower portion of the gate electrode. In addition, a silicide layer can be further formed on the source region, the drain region, and the gate electrode, respectively. Preferably, the source and drain regions comprise a low concentration diffusion region and a heavy concentration diffusion region. Second sidewall spacers can be formed on the low concentration diffusion regions, and at outer walls of the first sidewall spacers. Here, each portion of the silicide layer can be automatically separated by the second sidewall spacers.

In addition, a method for forming a transistor according to the present invention may comprise the steps of forming a mask layer on a semiconductor substrate, the mask layer including an opening; forming a trench or groove having a predetermined depth by etching the substrate using the mask layer as an etching mask; forming sidewall spacers on inner sidewalls of the trench or groove and the mask layer; forming a gate insulating layer on a surface of the substrate exposed by the opening; forming a gate electrode on the gate insulating layer between the first sidewall spacers; removing the mask layer; and forming source and drain regions in the substrate adjacent to the trench or groove.

The source/drain regions may each comprise a low concentration diffusion region and a heavy concentration diffusion region, wherein the low concentration diffusion region is formed by implantation of impurities in the substrate beside the trench or groove, after removing the mask layer; and the heavy concentration diffusion region is formed by implantation of impurities in the substrate after forming second sidewall spacers at outer walls of the first sidewall spacers.

A silicide layer may be formed on the gate electrode and the heavy concentration diffusion regions, respectively. The silicide layer can be automatically formed adjacent to the second sidewall spacers on source/drain regions. Alternatively, the silicide layers can be automatically formed adjacent to the first sidewall spacers, after removing the second sidewall spacers.

### BRIEF DESCRIPTION OF DRAWINGS

FIGS. 1 to 3 are cross-sectional views illustrating problems in a conventional method for forming a transistor.

FIG. 4 shows a cross-sectional view of a transistor according to a first embodiment of the present invention.

FIGS. 5 to 8 are cross-sectional views illustrating a method for forming a transistor according to the first embodiment of the present invention.

FIG. 9 shows a cross-sectional view illustrating another embodiment of a method for forming a transistor according to the present invention.

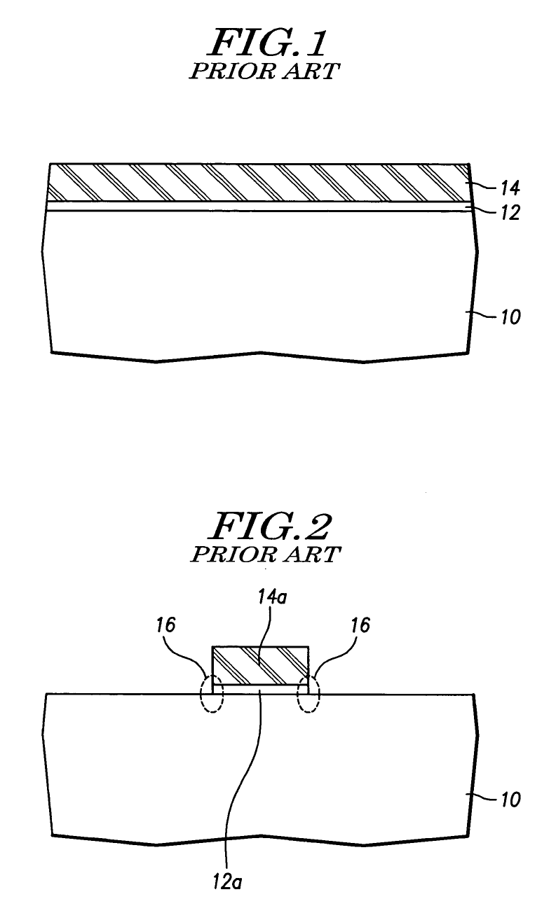

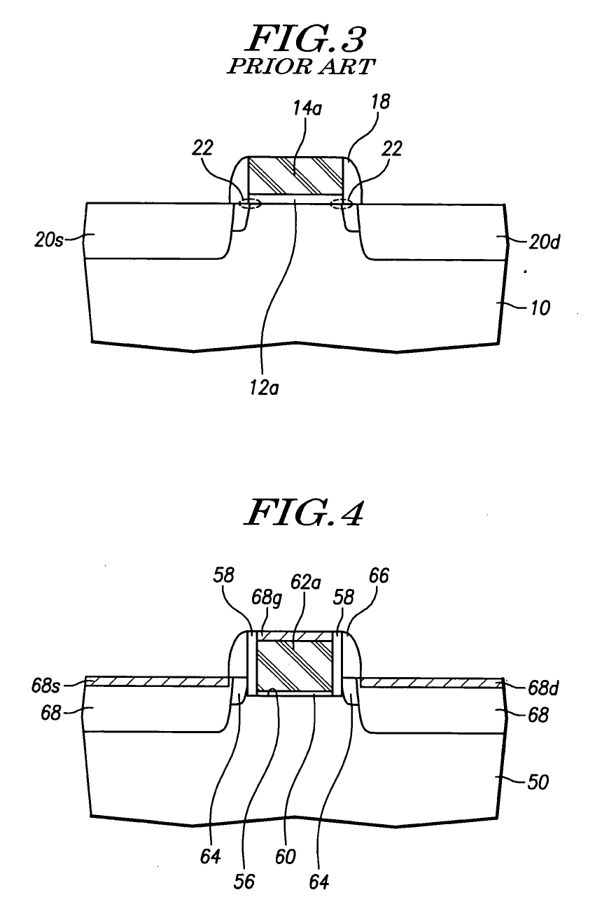

### DETAILED DESCRIPTION OF THE INVENTION

Hereinafter, preferred embodiments of the present invention will be described in detail referring to the following drawings.

FIG. 4 shows a cross-sectional view of a transistor according to a first embodiment of the present invention.

Referring to FIG. 4, a gate insulating layer 60 is formed on a bottom surface of a groove or trench 56 that is formed by etching a portion of a substrate 50 to a predetermined depth, and a gate electrode 62a is formed on the gate insulating layer 60. First sidewall spacers 58 are formed in the groove 56, and spacers 58 extend along both sides of the gate electrode 62a in upper direction. Source/drain regions comprise low concentration diffusion regions 64 and heavy concentration diffusion regions 68 formed in the substrate 50 adjacent opposed sides of the groove 56. Second sidewall spacers 66 are formed at outer walls of the first sidewall spacers 58, covering the low concentration diffusion regions 64. In addition, silicide layers 68g, 68s, and 68d can be respectively formed on top portions of the gate electrode 62a, the source region and the drain region. The silicide layers 68s and 68d are formed adjacent to the second sidewall spacers 66.

In the conventional structure, source and drain regions partially overlap with the gate electrode. As a result, currents through the transistor may leak due to a GIDL phenomenon. However, in the above-described transistor structure according to the invention, the gate electrode 62a is formed in and/or on the groove 56 of the substrate, and the first sidewall spacers 58 are formed at inner sidewalls of the groove 56. Accordingly, source and drain regions can be formed not to overlap with the gate electrode 62a.

FIGS. 5 to 8 are cross-sectional views illustrating a method for forming a transistor according to the first embodiment of the present invention.

Referring to FIG. 5, a buffer insulating layer 52 comprising an oxide material is formed on a substrate 50 (e.g., silicon dioxide formed by conventional chemical vapor deposition or thermal growth), and then a mask layer 54 is formed on the buffer insulating layer 52. The mask layer 54 can comprise a silicon nitride layer. The buffer insulating layer 52 lessens or eliminates stresses applied to the substrate by the mask layer 54 (e.g., silicon nitride). In the case where the mask layer 54 comprises or consists essentially of an insulating material having a low stress to the substrate, such as silicon oxide, etc., the buffer insulating layer 52 can be omitted.

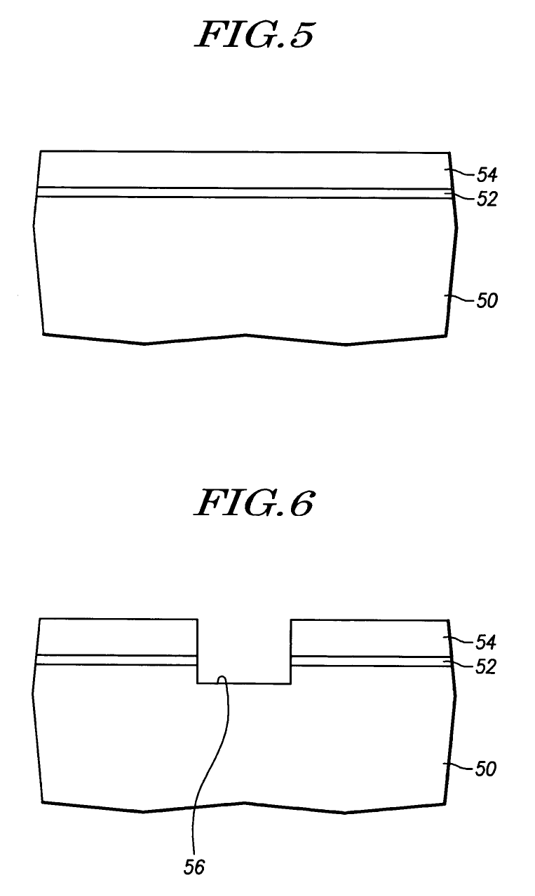

Referring to FIG. 6, the mask layer 54 and the buffer insulating layer 52 are etched, and then a portion of the substrate 50 is etched, thus forming a groove or trench 56 having a predetermined depth, and preferably, substantially vertical sidewalls and a substantially horizontal lower surface having a width (or length) of at least a critical dimension (e.g., a minimum feature size of the technology used for manufacturing the device). The groove 56 can be formed in a suitable depth, considering thicknesses of the gate insulating layer 60 and source/drain regions; e.g., the predetermined depth may be equal to or greater than a depth of the source/drain regions (or the depth of the low concentration regions of the source and drain).

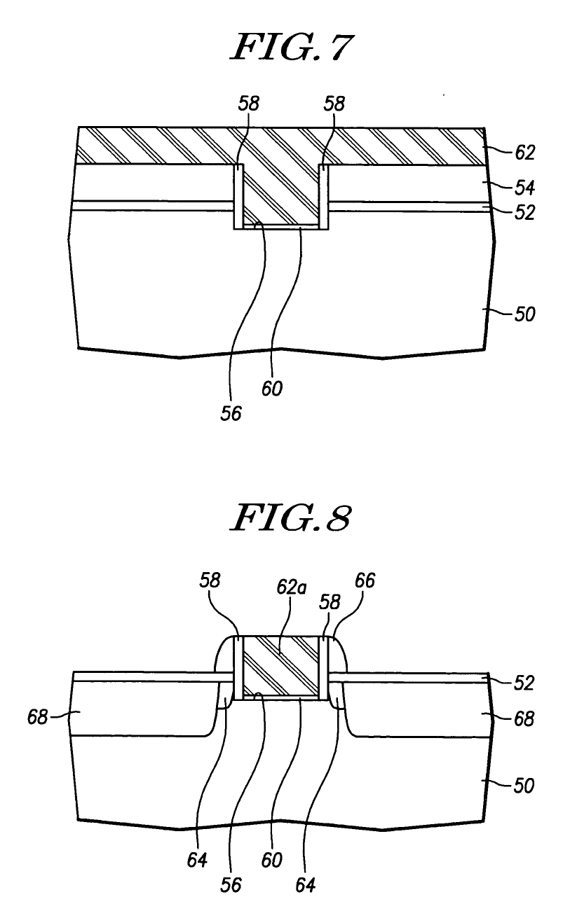

Referring to FIG. 7, a spacer insulating layer is formed on the mask layer 54 by conformal deposition of an insulating material (e.g., a low-pressure chemical vapor deposition process using TEOS, or tetraethyl orthosilicate), and then it is anisotropically etched to form first sidewall spacers 58 extending along the inner walls of the groove 56 (i.e., the inner walls of the substrate 50 and the mask layer 54). In addition, the gate insulating layer 60 is formed on the exposed substrate between the first sidewall spacers 58, generally by conventional thermal oxidation (e.g., when the exposed substrate surface comprises or consists essentially of silicon), although deposition of a suitable gate dielectric material and densification thereof (e.g., by rapid thermal annealing) may also be suitable (in which case a slightly thinner layer of insulating material may be deposited for the first sidewall spacers 58). Comparing with a conventional structure in which a gate insulating layer may be damaged by plasma during patterning of a gate electrode, the gate insulating layer 60 is formed on the exposed portion of the substrate between first sidewall spacers 58 so that etch damage can be prevented.

Next, a conductive layer 62 for a gate electrode is formed on the gate insulating layer 60, filling the groove 56 (e.g., an opening in the mask layer 54). The conductive layer 62 can comprise a polysilicon layer, and further a metal layer or a metal silicide layer can be formed thereon (preferably after subsequent planarization; see, e.g., FIG. 8 and the discussion thereof below).

Subsequently, as shown in FIG. 8, the conductive layer 62 is planarized on the mask layer 54 (e.g., by conventional chemical mechanical polishing or conventional etch back) to form a gate electrode 62a on the gate insulating layer 60 in the trench 56. The top surface of the mask layer 54 is exposed by the planarization, and then the exposed mask layer 54 beside the gate electrode 62a is removed (e.g., by selectively etching the mask layer 54 relative to the other exposed materials; when the mask layer 54 comprises or consists essentially of silicon nitride, conventional wet etching with phosphoric acid may be employed). Thus, portions of first sidewall spacers 58 and the gate electrode 62a protrude over the substrate 50 (e.g., its uppermost surface). Afterward, one or more n-type dopants (e.g., As) or p-type dopants (e.g., BF₂) are implanted in the substrate 50, thus forming low concentration diffusion regions 64 adjacent to the first sidewall spacers 58. Low concentration diffusion regions 64 can also be considered as lightly doped drain (LDD) structures. In the first embodiment, the first sidewall spacers 58 at both sides of the gate electrode 62a are partially buried in the substrate 50 by a depth corresponding to the depth of the groove 56, which can prevent overlap of the low concentration diffusion regions 64 with the gate electrode 62a.

Thereafter, second sidewall spacers 66 can be further formed at exposed outer walls of the first sidewall spacers 58, in order to form source/drain regions. Then, one or more n-type dopants (e.g., P) or p-type dopants (e.g., B) are implanted in the substrate, thus forming heavy concentration diffusion regions 68 aligned with the second sidewall spacers 66. FIG. 8 shows a source/drain structure where heavy concentration diffusion region 68 is formed deeper than low concentration diffusion region 64. Alternatively, the source/drain regions can comprise a DDD structure where low concentration diffusion regions 64 are formed deeper than heavy concentration diffusion regions 68. Low and heavy concentration diffusion regions functions as a source or drain region of a transistor.

Continuously, the exposed buffer insulating layer 52 is removed, and then silicide layers 68s, 68d, and 68g are respectively formed on the source region, the drain region, and the gate electrode 62a by a typical silicidation process, as shown in FIG. 4. The silicide layers 68s and 68d are automatically separated by second sidewall spacers 66.

The silicide layers can be respectively formed on a whole surface of source or drain region, in order to further reduce the electrical resistance of the source or drain region.

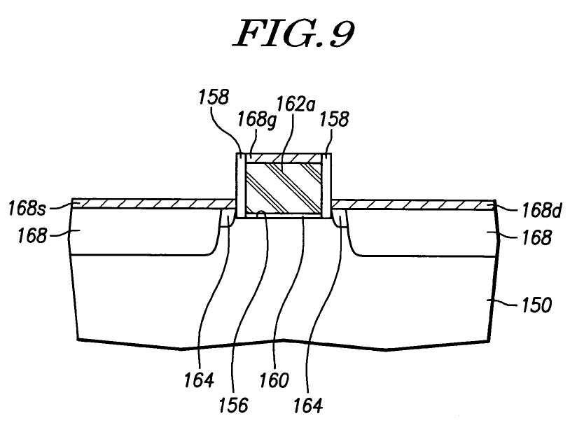

FIG. 9 shows a cross-sectional view illustrating another embodiment of a method for forming a transistor according to the present invention. This embodiment is similar to the first embodiment; however, it provides a transistor structure without second sidewall spacers 66.

Referring to FIG. 9, after forming low and heavy concentration diffusion regions 164 and 168 on the substrate 150, the second sidewall spacers 66 as shown in FIG. 8 are removed. In order to remove the second sidewall spacers while retaining the first sidewall spacers 158, it is preferable that the first sidewall spacers 158 comprise or consist essentially of a material having a high etching selectivity relative to the material for the second sidewall spacers.

When the outer walls of the first sidewall spacers 158 are exposed by removal of the second sidewall spacers, a silicidation process may be performed to form silicide layers 168s, 168d, and 168g on the source region, the drain region, and the gate electrode 162a, respectively. The silicide layers 168s and 168d are formed on both the heavy and low concentration diffusion regions 168 and 164, thus further reducing the electrical resistance of the source/drain regions relative to the transistor shown in FIGS. 4 and/or 8.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A transistor, comprising:
a trench or groove in a semiconductor substrate;
first sidewall spacers along inner sidewalls of the trench or groove, extending over an uppermost surface of the substrate;
a gate electrode between the first sidewall spacers;
a gate insulating layer between the gate electrode and the substrate; and
source and drain regions in the substrate adjacent to the trench or groove.

2. The transistor of claim 1, wherein the source and drain regions comprise a low concentration diffusion region and a heavy concentration diffusion region, and are separated from each other by a lower portion of the gate electrode.

3. The transistor of claim 1, further comprising a silicide layer on each of the source region, the drain region, and the gate electrode.

4. The transistor of claim 1, further comprising:
second sidewall spacers on outer walls of the first sidewall spacers; and
a silicide layer on each of the gate electrode, the source region and the drain region, respectively.

5. The transistor of claim 4, wherein the second sidewall spacers are between portions of the silicide layer.

6. A method for forming a transistor, comprising the steps of:
forming a mask layer on a semiconductor substrate, the mask layer including an opening;
forming a trench or groove by etching the substrate to a predetermined depth using the mask layer as an etching mask;
forming sidewall spacers on inner sidewalls of the trench or groove and the mask layer;
forming a gate insulating layer on a surface of the substrate exposed by the opening;
forming a gate electrode on the gate insulating layer between the first sidewall spacers;
removing the mask layer; and
forming source and drain regions in the substrate adjacent to the trench or groove.

7. The method of claim 6, wherein the step of forming the source and drain regions comprises:
forming low concentration diffusion regions in the substrate on opposed sides of the trench or groove;
forming second sidewall spacers on outer walls of the first sidewall spacers; and
forming heavy concentration diffusion regions in the substrate in alignment with the second sidewall spacers.

8. The method of claim 7, further comprising the step of forming a silicide layer on the gate electrode and the heavy concentration diffusion regions, respectively.

9. The method of claim 7, further comprising the steps of:
removing the second sidewall spacers; and
forming a silicide layer on the low concentration diffusion region, the heavy concentration diffusion region, and the gate electrode.

10. The method of claim 6, wherein the predetermined depth is equal to or greater than a depth of the source and drain regions.
